(19) United States
(12) Patent Application Publication
(10) Pub. No.: US 2006/0216614 A1
(43) Pub. Date: Sep. 28, 2006

(54) Method of mask making and structure thereof for improving mask ESD immunity

(75) Inventors: Shyh-Jen Guo, Taichung City (TW); Yu Loung Lo, Sinwu Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/089,061

(22) Filed: Mar. 24, 2005

(51) Int. Cl. G03C 5/00; G03F 1/00

(52) U.S. Cl. 430/5; 430/322; 430/323; 430/324

(57) ABSTRACT

A method for fabricating a mask (or reticle) to improve the mask ESD immunity is provided. A substrate having an upper surface is substantially transparent to a selected radiation. A light sensitive layer is formed over the substrate. The light sensitive layer is patterned and etched to form a pattern of openings in the light sensitive layer. The substrate is etched according to the pattern of openings in the light sensitive layer. The light sensitive layer is stripped. An opaque layer is then deposited on the upper surface and in the openings of the patterned substrate. The substrate is planarized by removing excess opaque layer from over the upper surface of the substrate. A pellicle is then mounted outstretched on the upper surface of the substrate.

### BACKGROUND

The present invention relates generally to methods for forming a mask used in the manufacture of integrated circuits, and more specifically, to the formation and structure of a mask for reducing electrostatic discharge.

In semiconductor manufacture, photomasking is used in the formation of integrated circuits on a semiconductor wafer. During a photomasking process, ultraviolet light is passed through a mask (or reticle) and onto the semiconductor wafer. The mask contains opaque and transparent areas or regions formed in a predetermined pattern. The ultraviolet light passes through the mask pattern and onto a layer of photoresist formed on the wafer. The resist is then developed and the patterned resist can be used during a subsequent semiconductor fabrication process such as ion implantation or etching.

In general, the mask comprises a smooth and transparent template of glass or quartz as its foundation and a layer of chromium (referred to as chrome), typically about 1,000 angstroms thick over the surface of the mask. The pattern with a transparent-opaque layout on the mask is etched onto the chrome layer for pattern transferring to the wafer. In photomasking, it is critical that a mask (or reticle) be perfectly manufactured. All wafer circuit features ultimately come from patterns on the mask; therefore, the quality of the mask plays a key role in achieving high-quality imaging during submicron photolithography. But the mask may be subject to damage, and these sources of damage may come from the misuse of the mask, such as dropping the mask, scratches on the surface, particles of dirt, and electrostatic discharge (ESD).

Sources of ESD problems may come from a mask that is handled by an improperly grounded technician or a dry environment. These conditions could potentially discharge a small surge of current through the micron-sized chrome lines on the mask surface, melting a circuit line and destroying the pattern. Moreover, an electric field may be formed on the mask which attracts particles in the air to the mask. Consequently, the pattern transferred through the mask can lose its clarity. The ESD problem is further compounded given that the pattern spacings are getting smaller and smaller as a result of shrinking feature sizes.

Most ESD problems are controlled through the proper use of equipment and procedures. Some of these include static-dissipative cleanroom materials, installing ex guard ring on masks, ESD grounding, and air ionization. However, methods of improving mask immunity to ESD by the mask itself has not hitherto been disclosed.

Accordingly, what is needed in the art is a method and structure thereof for manufacturing masks (or reticles) that improves the mask immunity to ESD.

### SUMMARY

The present invention is directed to methods for fabricating a mask (or reticle) to improve the mask ESD immunity. In one embodiment, a substrate having an upper surface is provided; the substrate is substantially transparent to a selected radiation. A light sensitive layer is formed over the substrate. The light sensitive layer is patterned and etched to form a pattern of openings in the light sensitive layer. The substrate is etched according to the pattern of openings in the light sensitive layer. The light sensitive layer is stripped. An opaque layer is then deposited on the upper surface and in the openings of the patterned substrate. The substrate is planarized by removing excess opaque layer from over the upper surface of the substrate. A pellicle is then mounted outstretched on the upper surface of the substrate.

In another embodiment, a mask is provided. The mask comprises a substrate substantially transparent to a selected radiation, the substrate having a plurality of openings formed therein and an opaque material is formed in the openings of the substrate.

### BRIEF DESCRIPTION OF THE DRAWINGS

The features, aspects, and advantages of the present invention will become more fully apparent from the following detailed description, appended claims, and accompanying drawings in which:

FIG. 1 is a schematic cross-sectional view of a formation of a mask showing a light sensitive layer formed on a substrate according to one embodiment of the present invention.

FIG. 2 is a schematic cross-sectional view of the structure of FIG. 1 showing a plurality of openings formed in the light sensitive layer after the steps of patterning and etching according to one embodiment of the present invention.

FIG. 3 is a schematic cross-sectional view of the structure of FIG. 2 showing etching of the substrate according to the pattern of openings in the light sensitive layer and the removal of the light sensitive layer according to one embodiment of the present invention.

FIG. 4 is a schematic cross-sectional view of the structure of FIG. 3 showing an opaque layer deposited on the upper surface and in the plurality of openings of the patterned substrate according to one embodiment of the present invention.

FIG. 5 is a schematic cross-sectional view of the structure of FIG. 4 showing the removal of excess opaque layer from over the upper surface of the substrate after a planarization step according to one embodiment of the present invention.

FIG. 6 is a schematic cross-sectional view of the structure of FIG. 5 showing a pellicle mounted outstretched on the upper surface of the substrate according to one embodiment of the present invention.

### DESCRIPTION

In the following description, numerous specific details are set forth to provide a thorough understanding of the present invention. However, one having an ordinary skill in the art will recognize that the invention can be practiced without these specific details. In some instances, well-known processes and structures have not been shown in detail to avoid unnecessarily obscuring the present invention.

The present invention is described with reference to specifically exemplary embodiments thereof. It will, however, be evident that various modifications and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

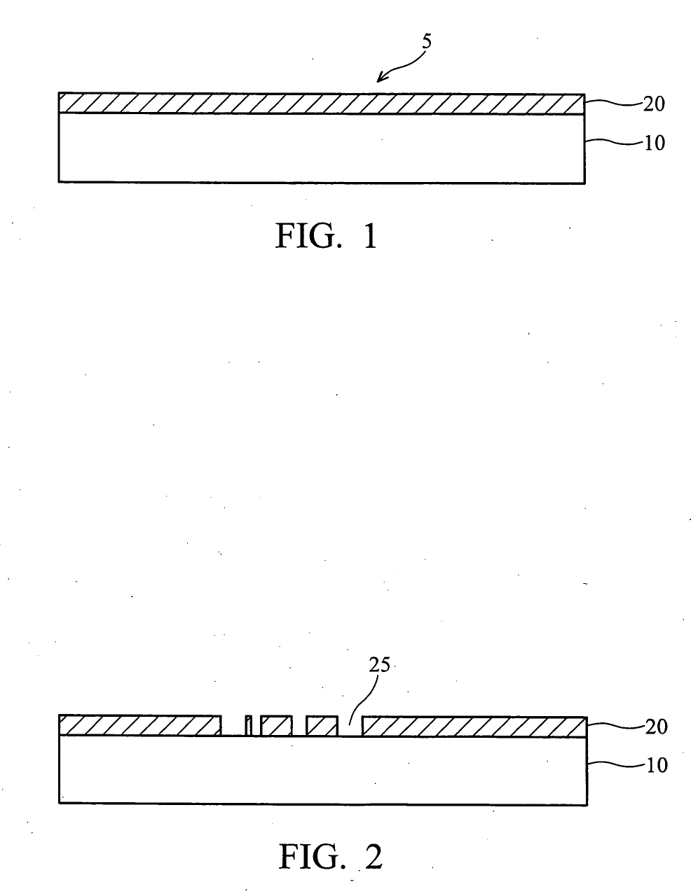

A method of fabricating a mask according to the present invention is illustrated in FIGS. 1 through 6. As is understood by those skilled in the art, a mask, sometimes called a photomask, is a transparent quartz template that has a pattern image that will be transferred to a photoresist coating on a wafer. The mask contains the pattern image for a complete wafer die array and the pattern is transferred in a single exposure. A reticle on the other hand, is a transparent quartz template that contains a pattern image that will be transferred to a part of the wafer (e.g., 5 die) and must be stepped and repeated across the entire substrate. It is understood that the discussion below with reference to mask fabrication may be equally applicable to reticle fabrication.

FIG. 1 is a schematic cross-sectional view of a formation of a mask showing a light sensitive layer formed on a mask substrate according to one embodiment of the present invention. Mask 5 comprises a substrate 10 that may in one embodiment comprise quartz. Other substrate materials such as fused silica or a semiconductor such as silicon may alternatively be used. Substrate 10 is chosen for its radiation transmission characteristics as well as its structural characteristics. An exemplary substrate may normally be about 6 mm thick, but this thickness may vary widely. In one embodiment of the present invention, substrate 10 may have a thickness of about 5 mm to about 10 mm. Light sensitive layer 20 may comprise a photoresist and may be applied onto substrate 10 by conventional spin coating techniques and may have a thickness of about 1,500 angstroms to about 8,000 angstroms. In another embodiment, light sensitive layer 20 comprises chemically amplified DUV (deep ultraviolet) resists for patterning device features having CDs (critical dimension) of 0.25 μm and below.

FIG. 2 is a schematic cross-sectional view of the structure of FIG. 1 showing a pattern of openings formed in the light sensitive layer after the steps of patterning and etching according to one embodiment of the present invention. Light sensitive layer 20 may be patterned using standard photolithographic techniques such as optical lithography or electron beam (e-beam) lithography to form the desired pattern of openings 25. Possible patterns may include the numerous device features, isolation trenches, contacts, metal interconnects, and vias to interconnect metal layers. After patterning, the light sensitive layer is then etched to remove the unwanted portions of light sensitive layer 20. Etching may be with a developer or similar processes.

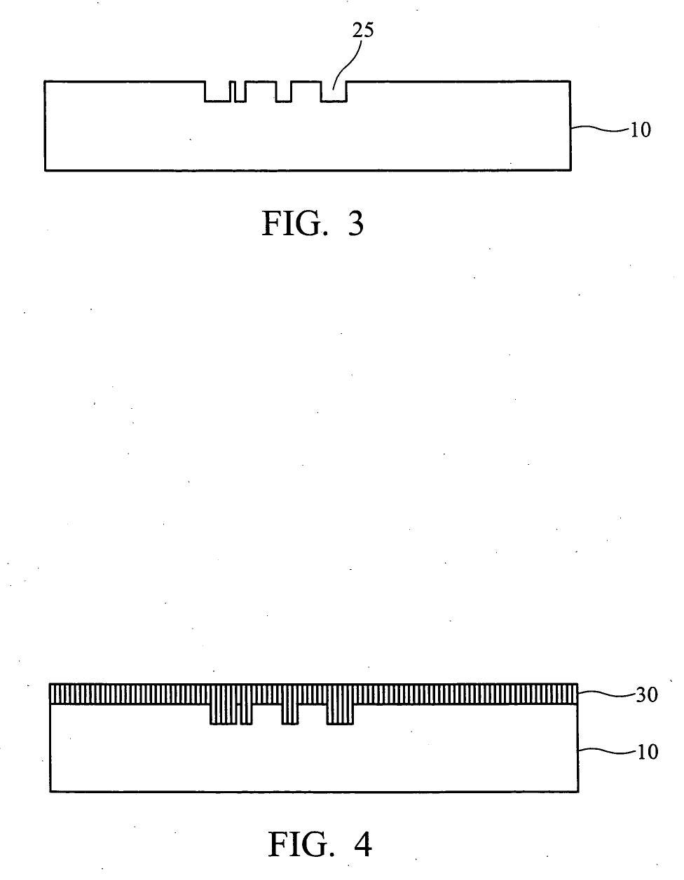

FIG. 3 is a schematic cross-sectional view of the structure of FIG. 2 showing etching of the substrate according to the pattern of openings in the light sensitive layer and the removal of the light sensitive layer according to one embodiment of the present invention. As ultraviolet light passes through the etched light sensitive layer 20, light sensitive layer 20 acts like a mask to transfer the pattern of openings 25 to substrate 10. Etching of substrate 10 may be by conventional etching techniques such as dry plasma etch. Light sensitive layer 20 is a temporary material placed on substrate 10 to transfer the pattern of openings 25 and is thereafter removed once the pattern is etched in substrate 10.

FIG. 4 is a schematic cross-sectional view of the structure of FIG. 3 showing an opaque layer deposited on the upper surface and in the plurality of openings of the patterned substrate according to one embodiment of the present invention. The most common opaque material deposited on substrate 10 is a thin layer of chrome. Opaque layer 30 preferably comprises chrome but may also comprise any of a large number of materials, such as metals including aluminum, gold, and silver. Opaque layer 30 may be deposited on patterned substrate 10 using a conventional process such as chemical vapor deposition (CVD), electron beam deposition (EBD), or sputtering. The thickness of opaque layer 30 is usually around 1,000 angstroms and in one embodiment may be deposited at a thickness of between about 800 angstroms and 5,000 angstroms. The thickness can be adjusted to set attenuation of the radiation. In fact, there may be regions of varying thicknesses depending upon the circuit pattern to be imaged on a wafer. An optional antireflective layer (not shown) of chromium oxide (about 0-300 angstroms thick) may also be formed on opaque layer 30.

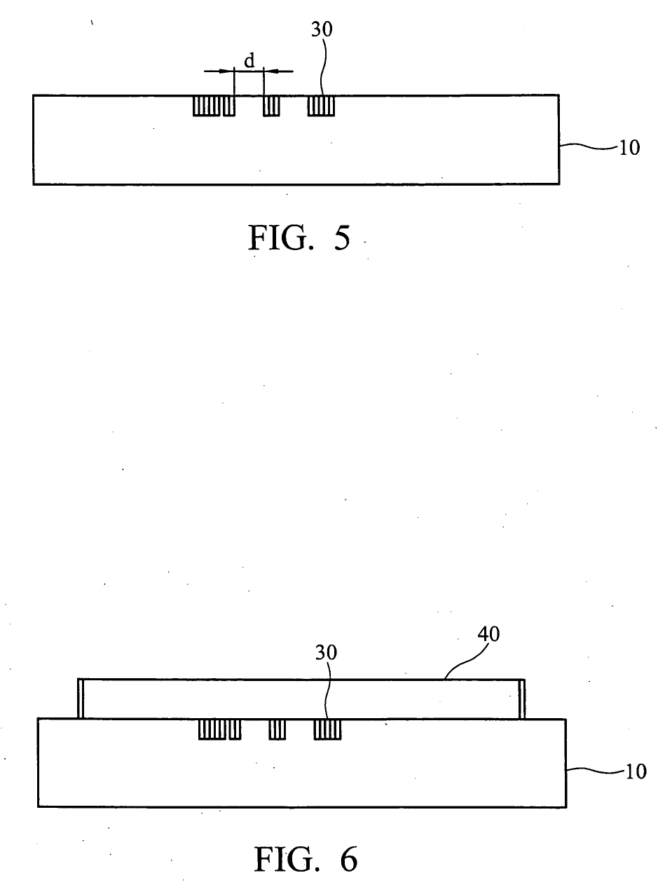

FIG. 5 is a schematic cross-sectional view of the structure of FIG. 4 showing the removal of excess opaque layer from over the upper surface of the substrate after a planarization step. The upper surface of substrate 10 may be planarized by the ubiquitous chemical mechanical planarization (CMP) technique. After planarization, opaque layer 30 is left in the pattern of openings 25. Unlike in the conventional mask making process where the patterned layer of chrome is formed above the mask substrate, in the present invention the patterned layer of chrome is formed in the mask substrate, preferably on the upper surface of the substrate. This has the advantage of improving the mask ESD immunity. Because the mask substrate comprises SiO2 or glass, its dielectric constant (k) is about 4.1 times that of air and it is this dielectric constant that is in a spacing “d” between the pattern of openings 25 shown in FIG. 5. On the other hand, in the conventional mask where the patterned layer of chrome is formed above the mask substrate with air in-between the pattern of the openings, the dielectric constant of air is 1. Because the mask of the present invention has a higher dielectric constant k, the induced voltage difference under specific electrostatic charging between the chrome patterns is lowered down to 1/k times of the conventional mask, and therefore lowers down the occurrence of ESD. Furthermore, its breakdown electric field strength is also higher than in the conventional mask. A higher breakdown electric field strength permits the mask of the present invention to withstand more induced static charges, thereby withstanding a higher ESD than in the conventional mask having lower breakdown electric field strength. Therefore, the method of forming a pattern of openings in the mask substrate of the present invention improves the mask ESD immunity over the conventional way of forming a pattern of openings above the mask substrate.

FIG. 6 is a schematic cross-sectional view of the structure of FIG. 5 showing a pellicle mounted outstretched on the upper surface of the substrate according to one embodiment of the present invention. A pellicle, an optically transparent membrane, is often used to protect the surface of a mask (or reticle) from airborne particulates that may land on critical regions of the mask and damage the circuit pattern and create an imaging defect. Pellicle 40 is tightly stretched on a sealed frame about 4 to 10 mm above the surface of substrate 10. Pellicle 40 is transparent to the exposing light energy and there are different materials and thicknesses that may be used for pellicle 40. In one embodiment, pellicle 40 comprises nitrocellulose acetate having a thickness of about 0.7 μm. In another embodiment, pellicle 40 comprises Mylar fluorocarbon material having a thickness of about 12 μm.

In the preceding detailed description, the present invention is described with reference to specifically exemplary embodiments thereof. It will, however, be evident that various modifications and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A method for forming a mask comprising the steps of:
providing a substrate having an upper surface, the substrate is substantially transparent to a selected radiation;
forming a light sensitive layer over the substrate;
patterning and etching the light sensitive layer to form a pattern of openings in the light sensitive layer;
etching the substrate according to the pattern of openings in the light sensitive layer; and
depositing an opaque layer on the upper surface and in the openings of the patterned substrate.

2. The method of claim 1, further comprising the step of:
stripping the light sensitive layer after the step of etching the substrate.

3. The method of claim 1, further comprising the step of:
planarizing the substrate by removing excess opaque layer from over the upper surface of the substrate.

4. The method of claim 1 further comprising the step of:
mounting a pellicle outstretched on the upper surface of the substrate.

5. The method of claim 1, wherein the substrate comprises quartz.

6. The method of claim 1, wherein the substrate comprises fused silica.

7. The method of claim 1, wherein the substrate comprises silicon.

8. The method of claim 1, wherein the light sensitive layer is a photoresist layer.

9. The method of claim 1, wherein the light sensitive layer has a thickness of from about 1,500 to 8,000 angstroms.

10. The method of claim 1, wherein the step of forming an opaque layer comprises a sputtering, CVD, or EBD step.

11. The method of claim 1, wherein the opaque layer comprises chrome.

12. The method of claim 1, wherein the opaque layer comprises metal.

13. The method of claim 1, wherein the opaque layer has a thickness of from about 800 to 5000 angstroms.

14. A mask comprising:
a substrate substantially transparent to a selected radiation, the substrate has a plurality of openings formed therein; and
an opaque material formed in the openings of the substrate.

15. The mask of claim 14, further comprising:
a pellicle mounted outstretched on the upper surface of the substrate.

16. A method for forming a reticle comprising the steps of:
providing a substrate having an upper surface, the substrate is substantially transparent to a selected radiation;
forming a light sensitive layer over the substrate;
patterning and etching the light sensitive layer to form a pattern of openings in the light sensitive layer;
etching the substrate according to the pattern of openings in the light sensitive layer; and
depositing an opaque layer on the upper surface and in the openings of the patterned substrate.

17. The method of claim 16, further comprising the step of:
stripping the light sensitive layer after the step of etching the substrate.

18. The method of claim 16, further comprising the step of:
planarizing the substrate by removing excess opaque layer from over the upper surface of the substrate.

19. The method of claim 16 further comprising the step of:
mounting a pellicle outstretched on the upper surface of the substrate.

20. A reticle comprising:
a substrate substantially transparent to a selected radiation, the substrate has a plurality of openings formed therein; and
an opaque material formed in the openings of the substrate.

21. The reticle of claim 20, further comprising:
a pellicle mounted outstretched on the upper surface of the substrate.
